(19) United States
(12) Patent Application Publication
(10) Pub. No.: US 2026/0047461 A1
(43) Pub. Date: Feb. 12, 2026

(54) SEMICONDUCTOR MODULE

(71) Applicant: Infineon Technologies AG, Neubiberg (DE)

(72) Inventors: Christian Müller, Schweinfurt (DE); Andressa Colvero Schittler, Ense (DE); Ulrich Nolten, Rüthen (DE); Thomas Raker, Geseke (DE)

(21) Appl. No.: 19/297,094

(22) Filed: Aug. 12, 2025

(30) Foreign Application Priority Data
Aug. 12, 2024 (DE) 102024207659.7

(51) Int. Cl. H01L 23/498; H01L 23/482; H01L 23/64; H01L 25/07

(52) U.S. Cl. CPC H01L 23/49844; H01L 23/482; H01L 23/64; H01L 25/072

(57) ABSTRACT

A semiconductor module includes: an insulator substrate; a first metallization layer arranged at the insulator substrate; and two or more controllable semiconductor elements arranged on a surface of the first metallization layer. Each controllable semiconductor element includes: a gate electrode; a first load electrode; a second load electrode; a control current path between the control electrode and the first load electrode; a controllable load current path between the first load electrode and the second load electrode; and a first circuit element arranged between the control current path and the load current path.

### TECHNICAL FIELD

The instant disclosure relates to a semiconductor module.

### BACKGROUND

Power semiconductor modules often include at least one semiconductor substrate arranged in a housing. A semiconductor arrangement including a plurality of controllable semiconductor elements (e.g., IGBTs, MOSFETs, HEMTs, etc.) is arranged on each of the at least one substrate. Each substrate usually comprises a substrate layer (e.g., a ceramic layer) which is an insulator layer and a first metallization layer deposited on a first side of the substrate layer. The substrate and the insulator layer may be referred to as an insulator substrate. The controllable semiconductor elements are mounted, for example, on the first metallization layer. In many applications, two or more individual controllable semiconductor elements are electrically coupled in parallel to each other in order to fulfill requirements concerning a current capability of the arrangement. However, when controllable semiconductor elements that are electrically coupled in parallel are switched on and off, oscillations may occur. One type of oscillation that may occur are so-called inter-chip oscillations, where the parasitic capacitances of the controllable semiconductor elements oscillate against parasitic inductances that are present between the respective controllable semiconductor elements.
A further type of oscillation is the oscillation between the switches'output capacitances and the parasitic inductance in the commutation cell (usually chip interconnects-, package leads-, busbar- and DC-link-capacitor-inductances as a sum). Such oscillations may cause EMI (electromagnetic interference) problems.

Hence, there is a general need for a semiconductor module in which oscillations, and in particular inter-chip oscillations, are significantly reduced.

### SUMMARY

According to a first aspect of the disclosure a semiconductor module comprises an insulator substrate; a first metallization layer arranged at the insulator substrate; two or more controllable semiconductor elements arranged on a surface of the first metallization layer, each controllable semiconductor element comprising a gate electrode, a first load electrode and a second load electrode, a control current path between the control electrode and the first load electrode, a controllable load current path between the first load electrode and the second load electrode, and a first circuit element arranged between the control current path and the load current path.

By virtue of the present disclosure, one or more central or de-central first circuit elements are presented, the first circuit elements being arranged between the gate and the source, all within a gate source current path within the semiconductor module, to avoid or mitigate undesired oscillations caused by geometrical and/or electrical asymmetries within the semiconductor module. By virtue of the present disclosure electrical asymmetries, or geometrical asymmetries causing electrical asymmetries may be diminished. This may be achieved by using accordingly designed first circuit elements, which are configured to balance electrical asymmetries in the layout. Thereby groups of controllable semiconductor elements within the semiconductor module can be decoupled, and dynamic current misdistribution effects can be reduced.

According to the first aspect, the semiconductor module comprises an insulator substrate, wherein the insulator substrate may consist of substrate and an insulator layer. The insulator layer may be arranged at the substrate, or on top of the substrate. A first metallization layer may be arranged on a topside plane of the insulator substrate forming electrically conductive structures. The electrically conductive structures may form current paths, which may connect to the controllable semiconductor elements. The controllable semiconductor elements may be switches which comprise a load current path and a control current path, which controls the load current path. The first circuit elements may be arranged at the substrate or connect different parts or structures at the substrate to one another. The first circuit element may be coupled between the control electrode and the first electrode, which may be a Source/Emitter electrode on a substrate-level. By implementing the first circuit element on a substrate-level, parasitic effects caused by contact pins and/or bond wires can be reduced. The term substrate-level may be used to express that the disclosure relates to an inside of a semiconductor module.

In an embodiment, the first metallization layer comprises a gate section, a second section, and at least a third section, and wherein the semiconductor module further comprises a plurality of first electrical connection elements, wherein the gate electrode of each controllable semiconductor element of the two or more controllable semiconductor elements is electrically coupled to the gate section by means of one or more of the first electrical connection elements, wherein the first load electrode of each controllable semiconductor element of the two or more controllable semiconductor elements is electrically coupled to the second section by means of one or more of the first electrical connection elements, and wherein the second load electrode of the two or more controllable semiconductor elements are electrically coupled to the third section by means of electrically conductive connection layers.

The first metallization layer may be arranged at the insulator substrate and may comprise various sections at various potentials. Specifically, the metallization layer comprises a gate section, a second section which may be a source/emitter section and a third section which may be a drain or collector section. Controllable semiconductor elements are coupled to the gate section and may be controlled therefrom. Therefore, the gate electrode of each controllable semiconductor element is coupled, i.e. electrically bonded, to the gate section. The first electrical connection elements may be e.g. bond wires, clamps, layer shaped structures etc.

In an embodiment, the first circuit element may be arranged between the gate section and the second section.

Particularly, the first circuit element may be electrically coupled between the gate section of the metallization layer and the second section, which may be the source/emitter section of the metallization layer. Thereby, an electrical coupling may be realized between both sections.

In particular, the gate section may be at a gate potential and the second section may be at a source/emitter potential, which is different from the gate potential.

In an embodiment, the load current path is formed between the second section and the third section.

In an embodiment, the circuit element is arranged atop the first metallization layer. The first circuit element may be arranged on the substrate level as a part of the metallization layer or as a separate part on top of the metallization layer. The circuit element may be part of the substrate and/or may be part of a layer structure of a multilayer substrate.

In an embodiment, the circuit element is a passive element. The term passive element refers to a type of electronic component that does not require an external power source to operate and/or does not require an external control path to operate. Instead, it can respond to an electrical signal or pass it along without adding energy to the circuit. Passive elements are fundamental building blocks in electronic circuits and are contrasted with active elements, which can introduce power gain. Some common examples of passive elements include resistors, capacitors, inductors, and transformers. Nevertheless, an active snubber circuit may also be possible.

In an embodiment, the passive element is an impedance. Impedance is a measure of the opposition that a circuit presents to the flow of an alternating current (AC). It is a complex quantity that includes both resistance and reactance. Resistance, measured in ohms, represents the opposition to the flow of current in a direct current (DC) circuit, while reactance arises from the effects of capacitance and inductance, and is also measured in ohms.

The impedance may be at least one of a capacitor, a resistor, or an inductor. As an alternative to capacitors, impedances can also generally be inserted into the gate-source path. These impedances, for example additive gate resistors, are used asymmetrically, as in the example of the capacitors, to adapt the switching properties of subsystems or sub-subsystems and to avoid or reduce oscillations.

In general, an asymmetrical compensation takes place both for capacitors and for impedances. That is to say that the additive passive components are not distributed symmetrically over all the chips of the parallel circuit but are used specifically (asymmetrically) for specific sub(sub)systems, a sub(sub)system either itself being a parallel circuit or a single chip.

If the passive element is a capacitor, the additionally introduced capacitance may be at maximum in the order of magnitude of 10% of the (total) capacitance to avoid an excessive increase in the total losses.

If the passive element is an additive gate resistor, the additionally introduced ohmic resistance may be at maximum in the order of magnitude of 10% of the (total) resistance in order likewise to avoid an excessive increase in the total losses. In this case, both an external and the internal gate resistor are to be taken into consideration as a reference.

While an additive capacitance primarily influences the switch-on behavior and therefore the di/dt, the switch-off behavior (in the case of MOSFETs) and the dv/dt can also be controlled by additive gate resistors. Regardless of the indicated guideline values for the selection of the capacitance and resistance values, much larger or even smaller values may also be implemented if a corresponding reduction in the oscillations can therefore be achieved.

In an embodiment, the gate section comprises at least a first sub-section and a second sub-section, wherein the first and the second sub-sections are electrically isolated from one another, and wherein the sub-sections are connected by a second circuit element.

The gate section may be subdivided into several subsections, for example into gate islands. The subsections may again be electrically connected to one another by second circuit elements. The second circuit elements may be passive elements, too.

Particularly the second circuit element may be an inductance, in particular a wire or a coil. The gate islands, i.e. the subsections, may be connected by wires. These wires have a resistance, but as well an inductance, which cannot be avoided. The wires and subsections of the gate section are at the same potential and form a gate current path. The first circuit elements may be applied as needed to outweigh an undesired influence of the second circuit elements which cannot be avoided.

In an embodiment, the first section comprises a third sub-section connected to the second sub-section via the second circuit element and wherein the control current path is formed starting at the first sub-section of the gate section via the second and third sub-sections to the gate electrode via the second circuit elements.

In an embodiment, each of the sub-sections controls at least two of the controllable semiconductor elements, and wherein the semiconductor elements are connected in parallel to one another via the respective sub-section. By virtue thereof, a high-inductance gate connection between the oscillating pair of controllable semiconductor devices is provided, guaranteeing additional damping between the oscillating devices. This drives effective gate inductance between the chips to a higher value, bringing the system to stability.

In an embodiment, the first sub-section is connected to the second section by a first circuit element, particularly by a first capacitor, and/or wherein the second sub-section is connected to the second section by a second first circuit element, and/or wherein the third sub-section is coupled to the second section by a third first circuit element. By sequentially connecting gate subsections with wires, various “gate intersections” may be formed along the gate current path. Each “intersection” may be electrically connected to a subset of the controllable semiconductor elements, connecting them in parallel. Thereby subsystems are formed within the set of semiconductor elements and each subsystem receives a separate gate-source capacitor or a gate-source impedance. This type of conversion makes it possible to avoid switching asymmetries (caused by magnetic fields) within a sub-system by reducing the switching speed of individual subsystems. If a plurality of components are connected in parallel and these components are contacted by a bond connection (stitching), an additional gate-source capacitor/impedance may be attached to each component in order to compensate for the accelerating effects of the gate inductance.

In an embodiment, a first subset of the controllable semiconductor elements is arranged symmetrically at the insulator substrate with respect to a second subset of the controllable semiconductor elements. By introducing geometrical symmetries into the layout of the semiconductor module, generally, electrical symmetry is enhanced. By enhancing electrical symmetry unwanted constructive interference effects of oscillating neighboring controllable semiconductor elements are reduced.

In an embodiment, the first circuit elements are capacitors which are soldered, sintered, clamped, glued, or electrically conductively coupled between the gate potential and the source potential.

In an embodiment, the capacitors are integrated and contacted at an additional substrate surface or wherein the capacitors are formed by an additional substrate (metal-insulator-metal) and are integrated into the semiconductor module.

In an embodiment, the additional substrate surface is an additional soldered substrate or a sintered substrate.

In an embodiment, the controllable semiconductor elements are at least one of a GaN HEMT, a SiC MOSFET, a Si IGBT, a Si MOSFET.

The invention may be better understood with reference to the following drawings and the description. The components in the figures are not necessarily to scale, emphasis instead being placed upon illustrating the principles of the invention. In the figures, like referenced numerals designate corresponding parts throughout the different views.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrate a schematic circuit diagram of an embodiment of the disclosure.

FIG. 2 illustrate a schematic side view of an embodiment.

FIG. 3 illustrate a schematic exemplary embodiment of the disclosure.

FIG. 4 illustrate another schematic exemplary embodiment of the disclosure of the embodiment of FIG. 3.

### FIG. 5A illustrate an Exemplary High-side embodiment.

FIG. 5B illustrate an exemplary low-side embodiment.

FIG. 6 illustrate a further low-side embodiment having two subsystems.

FIG. 7 illustrate a further low-side embodiment showing two sub-subsystems.

FIGS. 8A and 8B illustrate a further embodiment of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connecting pads and includes at least one semiconductor element with electrodes. The pads are electrically connected to the electrodes which includes that the pads are the electrodes and vice versa.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

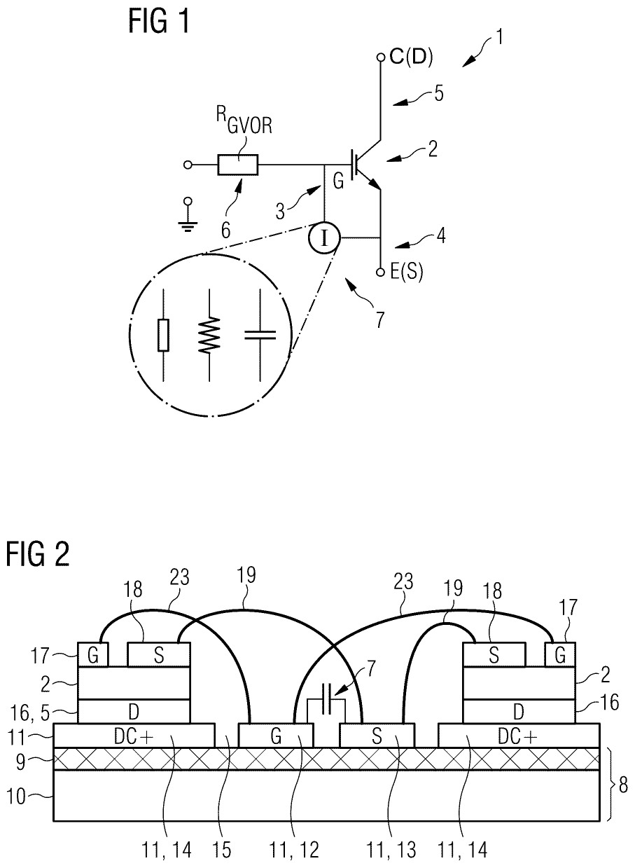

Referring to FIG. 1, a circuit diagram of the principle of the present disclosure is shown. A semiconductor (power) module 1 comprises a controllable semiconductor element 2. The semiconductor element 2 has a gate connector 3, a source connector 4 and drain connector 5. A gate series resistor 6 or additional gate resistor (R_{GVOR}?) is arranged in a gate current path. An impedance 7 is arranged between a gate potential and source potential. That is, the impedance 7 is coupled to the gate path between the gate connector 3 of the controllable semiconductor element 2 and the gate series resistor 6 on the one side, and to the source potential, that is, the source connector 4 on the other side. The impedance 7 can be one of a resistor, a coil, an inductance, a capacitor. The impedance 7 is generally arranged inside the module 1 on a substrate-level.

FIG. 2 is a schematic side view of an embodiment of FIG. 1, showing an exemplary implementation of an aspect of the disclosure on the substrate-level.

The semiconductor module 1 comprises an insulator substrate 8. The insulator substrate consists of an insulating layer 9 and a substrate 10. Alternatively, the substrate may be the insulator. In embodiments of the disclosure, the substrate may consist of a backside metallization layer, a ceramic Insulator and a frontside metallization layer. The insulating layer 9 covers the substrate 10. A first metallization layer 11, which may correspond to the frontside metallization layer, is disposed at the insulating layer 9. The metallization layer 11 may form a lead frame and comprises a gate section 12, a second section 13 which may be a source or emitter section and a third section 14. The third section 14 acts as a die pad for attaching the controllable semiconductor device 2. The third section 14 may be a DC−/+ section or an AC section. The sections are isolated from one another. Trenches 15 are formed between the sections wherein the bottom of each trench is a topside surface of the insulating layer 9. The controllable semiconductor elements 2 are arranged and electrically bonded to the third sections 14 with their lower surfaces, by a layer structure 16. Layer structure 16 may be a die attach adhesive, such as an epoxy comprising additives like silver flakes, reactive epoxy diluent or solvent, catalyst. Further, layer structure 16 may be a metallic solder, a sinter paste or film, or a preform. The lower surfaces of the controllable semiconductor elements 2 are drain/collector connectors/electrodes.

The controllable semiconductor elements 2 further comprise a gate electrode 17 and a source electrode 18. The gate electrode 17 is coupled to the gate section 12 by a second circuit element 23. The source electrode 18 is coupled to the second section 13 by one or more of the first electrical connection elements 19. Thereby, a gate current path is formed starting at the gate section 12 and extending via the second circuit element 23 to the gate electrode 17 of the respective controllable semiconductor element 2. A load current path is formed starting at the second section 13 via the first electrical connection element 19 towards the source electrode 18 of the controllable semiconductor element 2, thereby enabling a load current flow between the second section and the third section, which may be DC+ or AC, depending on whether the controllable semiconductor elements 2 form a high-side arrangement or a low-side arrangement.

An impedance 7 is arranged between the gate section 12 and the second section 13. In the present case, the impedance is a capacitor between the load current path and the gate current path.

The capacitor 7 is arranged atop the first metallization layer 11 in the gate source current path. Atop means that the capacitor is not part of the metallization layer, but a separate element connecting different sections of the metallization layer. Alternatively, the impedance 7 may be arranged in a trench 15 or be an additional soldered substrate which is arranged on one of the gate section 12 or the second section 13.

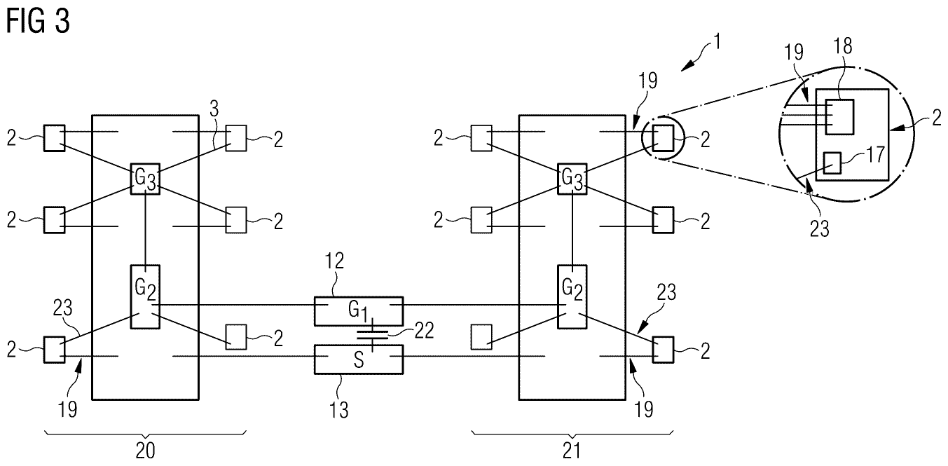

FIG. 3 is a further schematic exemplary embodiment of a semiconductor module 1 according to the present disclosure. The semiconductor module 1 comprises a plurality of controllable semiconductor elements 2. The controllable semiconductor elements 2 are subdivided into a first group 20 and a second group 21. The arrangement of the semiconductor elements 2 of the first group 20 is generally symmetrical to the arrangement of the semiconductor elements 2 of the second group 21.

Both groups are connected to a central gate section 12, which may be a central gate island formed within the first metallization layer 11 (not shown).

Generally, the gate section 12 at the metallization layer 11 is subdivided into several subsections. In FIG. 3, the central gate section 12 is a first sub-section G1 of the gate sections. The first sub-section G1 is followed by a second sub-section G2 and a third sub-section G3. The sub-sections G2 and G3 are sequentially connected to the central gate section G1, 12 and form part of a control current path. Both the second and the third sub-sections G2, G3 are connected to at least one pair of controllable semiconductor elements 2. The sub-sections are electrically connected by second circuit elements 23 to the gate electrodes 17 of the respective semiconductor element 2 of the respective pair of semiconductor elements 2.

Both groups 20, 21 are connected to a central source section 13, which is a central source island. The source section 13 corresponds to the second section 13 of FIG. 2. The source section 13 is electrically connected by a first electrical connection element 19 to a source island surrounding both the second and the third sub-sections G2, G3 of the gate island 12. The source island is electrically insulated from the gate sections G1-G3 and is at a source potential. The source island is part of the second section 13 described in relation with FIG. 2.

The source island is connected by a first electrical connection element 19, e.g. by a bond wire, to a source electrode 18 of the controllable semiconductor device 2. The source electrode 18 is a first load electrode and forms part of the load current path.

A first circuit element, which may be any kind of impedance 7, is arranged between the central gate section 12 and the central source section 13. In FIG. 3, the impedance is a capacitor 22. The capacitor 22 is coupled between the control current path and the load current path.

As the capacitor 22 is coupled between the central gate island and the central source island, the capacitor constitutes a retarding, damping and stabilizing element between the control current path and the load current path. Electrical asymmetries causing undesired oscillations, which may at least in part be caused by geometrical asymmetries can thereby be reduced.

If the switches are GaN HEMTs, the capacitor is located in a gate R-C link. GaN HEMTs may also comprise an additional snubber circuit between the gate electrode and the source electrode.

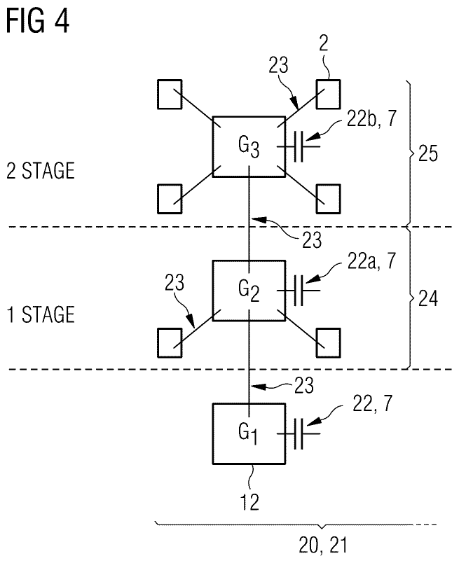

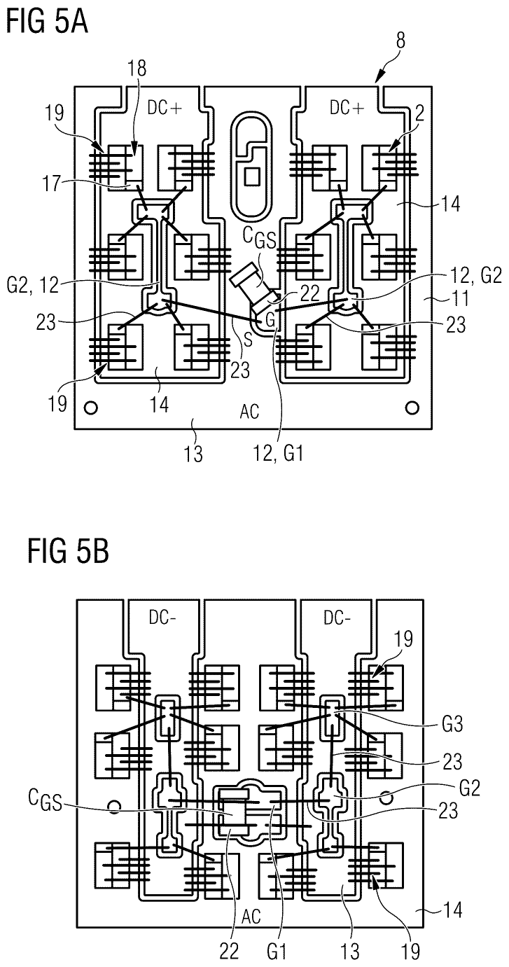

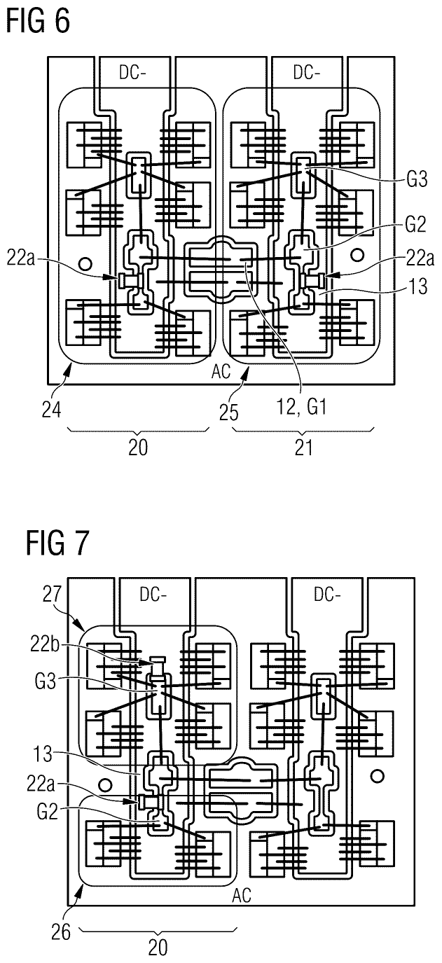

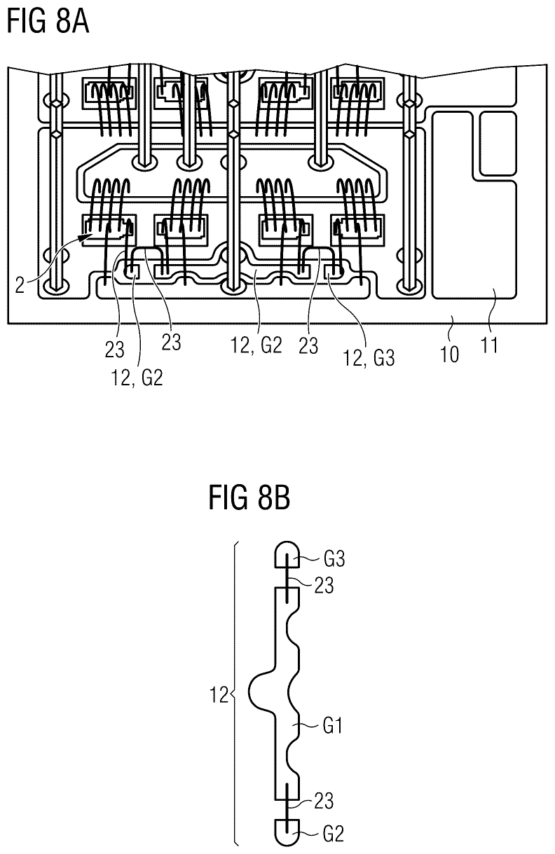

FIG. 4 shows a part of the control current path of FIG. 3. The central gate section G1, 12 is connected to the gate sub-sections G2 and G3 in series by second circuit elements 23. Each of the gate sub-sections G2 and G3 supply a control current to the gate electrodes 17 of at least one pair of substantially symmetrically arranged controllable semiconductor elements 2. Each of the gate sub-sections G2, G3 may be coupled by first circuit elements 22 to the surrounding source potential.

Depending on where in the control current path the impedance 7 is arranged, sub-systems of the semiconductor elements 2 are defined. Thereby a sub-system of the plurality of semiconductor elements 2 is defined by any sub-group of controllable semiconductor elements 2 which is further downstream in the control current path seen from the perspective of the impedance 7.

As an example, in FIG. 3, the impedance 7 is arranged such that the central gate island 12 is connected to the source potential, that is, source island 13. Subsequently, all the controllable semiconductor elements 2 being further “downstream”, that is, closer to the gate electrode 17 of a respective controllable element 2, are influenced by the impedance and hence form an electrical sub-system of the semiconductor device 1. Depending on a need to outbalance undesired effects due to electrical asymmetry, the electrical characteristics and the location of the impedance 7 can be selected.

As a further example, in FIG. 4, the impedance 7, which may be a capacitor 22, can be arranged such that the first gate sub-section G1 is coupled to the source potential. Thereby, all of the depicted semiconductor elements 2 form a common sub-system corresponding to the first and second group 20, 21. If an additional impedance, i.e. a further capacitor 22, is arranged between the second gate sub-section G3 and the source potential, the semiconductor elements are split of into a first sub-system 24 and a second sub-system 25. The first sub-system 24 comprises two symmetrically arranged downstream semiconductor devices 2 seen from the first gate sub-section G2. The second sub-system 25 comprises four symmetrically arranged downstream semiconductor devices 2 seen from the second gate sub-section G3.

FIG. 5A is an exemplary high-side embodiment according to the first aspect of the disclosure. Semiconductor elements 2 are coupled with the first load electrode 5 to the third section 14 of the metallization layer 11, which is at a DC+ potential in a high-side arrangement. The source electrode 18 is coupled to a source potential, e.g. AC, that is to the second section 13, by way of the first electrical connection elements 19. A load current path is formed between the source electrode 18 and the first load electrode 5. The load current path is controllable by the gate current path. The metallization layer 11 has a gate section 12. The gate section, which is at a gate potential, is subdivided into a first sub-section G1 and two second sub-sections G2. Each sub-section G2 is connected to sub-section G1 by the second circuit elements 23, which are wires in the present case. Sub-section G1 forms a central gate island. Sub-section G1 is connected to the second section 13, which is at the source potential, by capacitor 22. Capacitor 22 thereby links the gate current path to the load current path. As the capacitor 22 is arranged centrally, that is, at a starting point of the gate current path, it influences the behavior of all electrical elements, particularly the second circuit elements 23, which are further downstream in the gate current path. Hence, the switching behavior of the entire plurality of controllable semiconductor elements 2, that is the first group 20 and the second group 21 of controllable semiconductor elements 2, is influenced by one central impedance/capacitor 22.

FIG. 5B is an exemplary low-side embodiment corresponding to the high-side embodiment of FIG. 5A. Semiconductor elements 2 are coupled with the first load electrode 5 to the third section 14 of the metallization layer 11, which is at an AC potential in a low-side arrangement. The source electrode 18 of the controllable semiconductor elements 2 is coupled to a source potential, that is, to the second section 13, which is at a DC-potential in a low side-arrangement, by way of the first electrical connection elements 19. The gate section 12 is subdivided into a first sub-section G1, a second sub-section G2 and a third sub-section G on each side of the parallel arrangement. The sub-sections G1-G3 are connected to one another in series by the wires 23, forming the gate current path. The capacitor 22 is arranged between the central gate island 12, G1 and a central second section 13. The central second section 13 forms a source island.

FIG. 6 is a further low-side embodiment having two subsystems. The first sub-system 24 is formed by arranging, within the first group 20 of controllable semiconductor elements 2, a first stage capacitor 22a between gate sub-section G2 and the source section 13. The first sub-system 24 comprises the first group 20 of controllable semiconductor elements 2. The second sub-system 25 is formed by arranging, within the second group 21 of controllable semiconductor elements 2, a first stage capacitor 22a between the second gate sub-section G2 and the source section. Consequently, the second sub-system 25 comprises the second group 21 of controllable semiconductor elements 2.

FIG. 7 is a further embodiment having two sub-subsystems. First sub-system 24 comprising the first group 20 of controllable semiconductor elements 2 is further subdivided into a first sub-sub-system 26 and a second sub-sub-system 27. The first sub-sub-system 26 is formed by arranging the first stage capacitor 22a between the second gate sub-section G2 and the source section 13. The second sub-sub-system 27 is formed by arranging a second stage capacitor 22a between the third gate sub-section G3 and the source section 13.

FIGS. 8A and 8B show an embodiment of a gate section 12 having sub-sections G1, G2 and G3. FIG. 8B is a detailed view of the gate section 12 of FIG. 8A.

Gate section 12 is formed by a section of the metallization layer 11 on the insulator substrate 8. Gate section 12 is subdivided into sub-sections G1-G3 of the metallization layer 11 forming islands on the insulator substrate 8. The islands are connected to one another by the second circuit elements 23. The second circuit element 23 in FIG. 8A is a portal shaped wire structure, which assumes at least some of the electrical characteristics of a coil. The second circuit element hence forms an inductance. The gate islands are hence coupled by inductive elements. Hence, inductive elements are arranged within the gate current path, driving the gate current and hence influencing the switching speed of further downstream controllable semiconductor elements 2.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### LIST OF REFERENCE SIGNS

1 Semiconductor module
2 Controllable semiconductor element
3 Gate connector
4 Source/Emitter connector
5 Drain/Collector connector
6 Gate series resistor
7 Impedance
8 Insulator substrate
9 Insulating layer
10 Substrate
11 First Metallization layer
12 Gate section G
G1 first sub-section of the gate section
G2 second sub-section of the gate section
G3 third sub-section of the gate section
13 Second section S
14 Third section DC+/−/AC
15 Trenches
16 Layer structure/Die Attach
17 Gate electrode
18 Source electrode
19 First electrical connection elements
20 First group
21 Second group
22 Capacitor/Impedance
22a first stage capacitor
22b second stage capacitor
23 Second circuit element
24 First sub-system
25 Second sub-system
26 First sub-sub-system
27 Second Sub-sub-system

What is claimed is:

1. A semiconductor module comprising:
an insulator substrate;
a first metallization layer arranged at the insulator substrate;
two or more controllable semiconductor elements arranged on a surface of the first metallization layer, each controllable semiconductor element comprising:
a gate electrode;
a first load electrode;
a second load electrode;
a control current path between the control electrode and the first load electrode;
a controllable load current path between the first load electrode and the second load electrode; and
a first circuit element arranged between the control current path and the load current path.

2. The semiconductor module of claim 1,
wherein the first metallization layer comprises a gate section, a second section, and at least a third section,
wherein the semiconductor module further comprises a plurality of first electrical connection elements,
wherein the gate electrode of each controllable semiconductor element of the two or more controllable semiconductor elements is electrically coupled to the gate section by one or more of the first electrical connection elements,
wherein the first load electrode of each controllable semiconductor element of the two or more controllable semiconductor elements is electrically coupled to the second section by one or more of the first electrical connection elements, and
wherein the second load electrode of the two or more controllable semiconductor elements are electrically coupled to the third section by electrically conductive connection layers.

3. The semiconductor module of claim 2, wherein the first circuit element is arranged between the gate section and the second section.

4. The semiconductor module of claim 2, wherein the gate section is at a gate potential and the second section is at a source potential, which is different from the gate potential.

5. The semiconductor module of claim 2, wherein the load current path is formed between the second section and the third section.

6. The semiconductor module of claim 1, wherein the first circuit element is arranged atop the first metallization layer.

7. The semiconductor module of claim 1, wherein the first circuit element is a passive element.

8. The semiconductor module of claim 7, wherein the passive element is an impedance.

9. The semiconductor module of claim 8, wherein the impedance is at least one of a capacitor, a resistor or an inductor.

10. The semiconductor module of claim 2, wherein the gate section comprises at least a first sub-section and a second sub-section electrically isolated from one another, and wherein the first sub-section and the second sub-section are connected by a second circuit element.

11. The semiconductor module of claim 10, wherein the second circuit element is a wire or a coil.

12. The semiconductor module of claim 10, wherein the first section comprises a third sub-section connected to the second sub-section via the second circuit element, and wherein the control current path is formed starting at the first sub-section of the gate section via the second and third sub-sections to the gate electrode via the second circuit elements.

13. The semiconductor module of claim 12, wherein each of the sub-sections controls at least two of the controllable semiconductor elements, and wherein the semiconductor elements are connected in parallel to one another via the respective sub-section.

14. The semiconductor module of claim 12, wherein the first sub-section is connected to the second section by the first circuit element, and/or wherein the second sub-section is connected to the second section by a second first circuit element, and/or wherein the third sub-section is coupled to the second section by a third first circuit element.

15. The semiconductor module of claim 1, wherein a first subset of the controllable semiconductor elements is arranged symmetrically at the insulator substrate with respect to a second subset of the controllable semiconductor elements.

16. The semiconductor module of claim 1, wherein the first circuit element of each of the controllable semiconductor elements is a capacitor soldered, sintered, clamped, glued, or electrically conductively coupled between a gate potential and a source potential.

17. The semiconductor module of claim 16, wherein the capacitor of each of the controllable semiconductor elements is integrated and contacted at an additional substrate surface or formed by an additional substrate (metal-insulator-metal) integrated into the semiconductor module.

18. The semiconductor module of claim 17, wherein the additional substrate surface is an additional soldered substrate.

19. The semiconductor module of claim 1, wherein the controllable semiconductor elements are at least one of a GaN HEMT, a SiC MOSFET, a Si IGBT, and a Si MOSFET.
